(19) United States
(12) Patent Application Publication
(10) Pub. No.: US 2007/0045668 A1
(43) Pub. Date: Mar. 1, 2007

(54) Vertical anti-blooming control and cross-talk reduction for imagers

(75) Inventors: Frederick T. Brady, Meridian, ID (US); Richard A. Mauritzson, Meridian, ID (US)

Correspondence Address: DICKSTEIN SHAPIRO LLP, 1825 EYE STREET NW, Washington, DC, 20006-5403, US

(73) Assignee: Micron Technology, Inc.

(21) Appl. No.: 11/211,490

(22) Filed: Aug. 26, 2005

(51) Int. Cl. H01L 29/768

(52) U.S. Cl. 257/219

(57) ABSTRACT

The present invention provides a solid-state imager device having a patterned buried doped region in the substrate, preferably an n+ doped region, that collects excess electrons and thus reduces cross-talk, minimizes blooming of excess electrons, and reduces dark current in a solid-state imager device.

### FIELD OF THE INVENTION

The present invention relates generally to imaging devices and fabrication methods for forming an imaging pixel cell.

### BACKGROUND OF THE INVENTION

Solid state imager devices which include charge-coupled-devices (CCD) and complementary metal oxide semiconductor (CMOS), have commonly been used in photo-imaging applications.

Imager devices typically contain thousands of pixel cells in a pixel array on a single chip. Pixel cells convert light into an electrical signal that can then be stored and recalled by an electrical device such as, for example, a processor. The electrical signals that are stored may be recalled to produce an image on, for example, a computer screen or a printable media.

Exemplary CMOS imaging circuits, processing steps thereof, and detailed descriptions of the functions of various CMOS elements of an imaging circuit are described, for example, in U.S. Pat. No. 6,140,630, U.S. Pat. No. 6,376,868, U.S. Pat. No. 6,310,366, U.S. Pat. No. 6,326,652, U.S. Pat. No. 6,204,524, and U.S. Pat. No. 6,333,205, each of which is assigned to Micron Technology, Inc. The disclosures of each of the forgoing patents are hereby incorporated by reference in their entirety.

Solid state imager devices typically have an array of pixel cells containing photosensors, where each pixel cell produces a signal corresponding to the intensity of light impinging on that element when an image is focused on the array. These signals may then be used, for example, to display a corresponding image on a monitor or otherwise used to provide information about the optical image. The photosensors are typically photogates, phototransistors, photoconductors or photodiodes, where the conductivity of the photosensor corresponds to the intensity of light impinging on the photosensor. The magnitude of the signal produced by each pixel cell, therefore, is proportional to the amount of light impinging on the photosensor.

CMOS active pixel sensor (APS) solid state imaging devices are described, for example, in the foregoing patents. These imaging devices include an array of pixel cells, arranged in rows and columns, that convert light energy into electric signals. Each pixel includes a photodetector and one or more active transistors. The transistors typically provide amplification, read-out control and reset control, in addition to producing the electric signal output from the cell.

While CCD technology has a widespread use, CMOS imagers are being increasingly used as low cost imaging devices. A CMOS imager circuit includes a focal plane array of pixel cells, each one of the cells including a photoconversion device, for example, a photogate, photoconductor, phototransistor, or a photodiode for accumulating photo-generated charge in a portion of the substrate. A readout circuit is connected to each pixel cell and includes at least an output transistor, which receives photogenerated charges from a doped diffusion region and produces an output signal which is periodically read out through a pixel access transistor. The imager may optionally include a transistor for transferring charge from the photoconversion device to the diffusion region or the diffusion region may be directly connected to or be part of the photoconversion device. A transistor is also typically provided for resetting the diffusion region to a predetermined charge level before it receives the photoconverted charges.

In a CMOS imager, the active elements of a pixel cell perform the necessary functions of: (1) photon to charge conversion; (2) accumulation of image charge; (3) transfer of charge to a floating diffusion region accompanied by charge amplification; (4) resetting the floating diffusion region to a known state; (5) selection of a pixel cell for readout; and (6) output and amplification of a signal representing the pixel cell charge. Photo-charge may be amplified when it moves from the initial charge accumulation region to the floating diffusion region. The charge at the floating diffusion region is typically converted to a pixel output voltage by a source follower output transistor.

To detect color, the spectral components of incident light must be separated and collected. An absorptive color filter array (CFA) on top of an imager chip may be used for color detection in a solid state image sensor, for example, a CCD or CMOS imager. In a typical CFA layout, a color filter for each individual photosensor of the imager allows only a narrow spectral band (red, green, or blue) to pass, and absorbs the rest of the photo energy.

Each pixel cell receives light that may have been focused through one or more micro-lenses. Micro-lenses on a CMOS imager help increase optical efficiency and reduce optical cross-talk between pixel cells. A reduction of the size of the pixel cells allows for a greater number of pixel cells to be arranged in a specific pixel cell array, thereby increasing the resolution of the array. In one process for forming micro-lenses, the radius of each micro-lens is correlated to the size of the pixel cell. Thus, as the pixel cells decrease in size, the radius of each micro-lens also decreases.

Electrical cross-talk is also a problem with imaging devices. Electrical cross-talk occurs when photo-generated charge from a pixel is collected by an adjacent or neighboring pixel. For example, an electron generated in the silicon under the red pixel, rather than diffusing up to be collected by the red photodiode, may have a significant lateral component, and be collected by an adjacent green photodiode.

Cross-talk can bring about undesirable results in the images that are produced. The undesirable results can become more pronounced as the density of pixel cells in imager arrays increases, and as pixel cell size correspondingly decreases. The shrinking pixel cell size also make it increasingly difficult to focus incoming light on the photosensor of each pixel cell, aggravating cross-talk.

Cross-talk can manifest as a blurring or reduction in contrast in images produced by a solid-state imager. In essence, cross-talk in an image sensor array degrades the spatial resolution, reduces overall sensitivity, causes color mixing, and leads to image noise after color correction. As noted above, image degradation can become more pronounced as pixel cell and device sizes are reduced.

Another problem in conventional imager devices is blooming or saturation. Blooming occurs when too many photons strike a particular pixel cell and the generated electrons overflow into adjacent pixel cells, artificially increasing the electron counts of those pixel cells.

Another common problem associated with conventional imager pixel cells is dark current, that is, current generated as a photo-conversion device signal in the absence of light. Dark current may be caused by many different factors, including: photosensor junction leakage, leakage along isolation edges, transistor sub-threshold leakage, drain induced barrier lowering leakage, gate induced drain leakage, trap assisted tunneling, and pixel cell fabrication defects.

There is needed, therefore, an imager device having reduced cross-talk, reduced blooming and decreased dark current. Also needed is a simple method of fabricating and operating such a pixel.

### BRIEF SUMMARY OF THE INVENTION

The present invention provides an imager method and apparatus for reducing electrical color cross-talk. The invention also reduces blooming of excess electrons and reduces dark current.

The present invention provides an imager device having a buried doped region in the substrate, preferably an n+ doped region, that collects excess electrons and thus reduces cross-talk, reduces blooming of excess electrons and reduces dark current.

Additional advantages and features of the present invention will be apparent from the following detailed description and drawings which illustrate preferred embodiments of the invention.

### BRIEF DESCRIPTION OF THE DRAWINGS

FIG. 1 illustrates a schematic cross-sectional view of an imager pixel cell having a buried doped region constructed in accordance with an exemplary embodiment of the present invention.

FIG. 2 is a representative diagram of the imager pixel cell of FIG. 1.

FIG. 3 illustrates a schematic cross-sectional view of an imager pixel cell having a buried doped region under the isolation regions constructed in accordance with an exemplary embodiment of the present invention.

FIG. 4 illustrates a cross-sectional view of a semiconductor wafer undergoing the process of forming a buried doped region according to an exemplary embodiment of the present invention.

FIG. 5 illustrates the semiconductor wafer of FIG. 4 at a stage of processing subsequent to that shown in FIG. 4.

FIG. 6 illustrates the semiconductor wafer of FIG. 4 at a stage of processing subsequent to that shown in FIG. 5.

FIG. 7 illustrates the semiconductor wafer of FIG. 4 at a stage of processing subsequent to that shown in FIG. 6.

FIG. 8 illustrates the semiconductor wafer of FIG. 4 at a stage of processing subsequent to that shown in FIG. 7.

FIG. 9 illustrates the semiconductor wafer of FIG. 4 at a stage of processing subsequent to that shown in FIG. 8.

FIG. 10 shows an imager constructed in accordance with an embodiment of the invention.

FIG. 11 is an illustration of an imaging system having an imager according to an exemplary embodiment of the present invention.

### DETAILED DESCRIPTION OF THE INVENTION

In the following detailed description, reference is made to the accompanying drawings, which form a part hereof and show by way of illustration specific embodiments in which the invention may be practiced. These embodiments are described in sufficient detail to enable those skilled in the art to practice the invention, and it is to be understood that other embodiments may be utilized, and that structural, logical, and electrical changes may be made without departing from the spirit and scope of the present invention. The progression of processing steps described is exemplary of embodiments of the invention; however, the sequence of steps is not limited to that set forth herein and may be changed as is known in the art, with the exception of steps necessarily occurring in a certain order.

The term “substrate” is to be understood to include any semiconductor-based structure. The semiconductor structure should be understood to include silicon, silicon-on-insulator (SOI), silicon-on-sapphire (SOS), silicon-germanium, doped and undoped semiconductors, epitaxial layers of silicon supported by a base semiconductor foundation, and other semiconductors and semiconductor structures. When reference is made to the substrate in the following description, previous process steps may have been utilized to form regions or junctions in or over the base semiconductor or foundation. The semiconductor also need not be formed of silicon, but may be formed of other semiconductor materials.

The terms “pixel” and “pixel cells” as used herein, refer to a photo-element unit cell containing at least one photosensor and additional structure for converting photons to an electrical signal. For purposes of illustration, a single representative pixel cells and its manner of formation are illustrated in the figures and description herein; however, typically fabrication of a plurality of like pixel cells proceeds simultaneously. Accordingly, the following detailed description is not to be taken in a limiting sense, and the scope of the present invention is defined only by the appended claims.

The following description of the invention is provided within the exemplary environment of a CMOS pixel using a pinned photodiode as a photosensor; however, the invention is not limited to use in a CMOS imager or to use in a CMOS imager employing a pinned photodiode as a photosensor. Any type of photosensor may be used in the invention including photodiodes, photogates, and other photosensing devices.

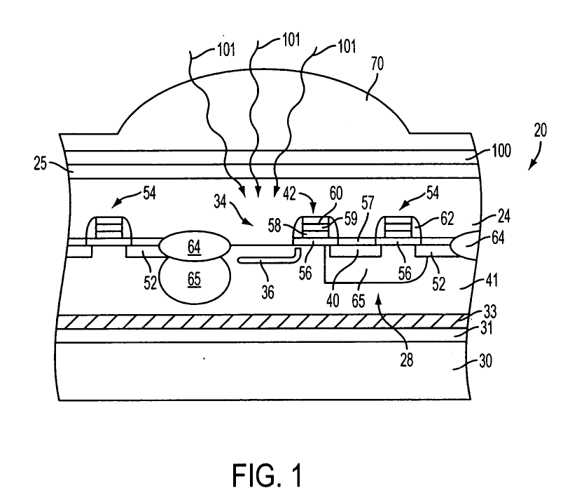

FIG. 1 shows an expanded view of a portion of a solid-state imager 20 according to one embodiment of the present invention. The solid-state imager 20 comprises a plurality of pixel cells 28 formed in and over a substrate 30 organized into an array of rows and columns. The substrate 30 is preferably a p+ substrate. A first p-epitaxial layer 31 is formed over the p+ substrate 30. A n+ doped layer 33 is formed between the first p− epitaxial layer 31 and a second p− epitaxial layer 41. It should be noted that the substrate 30 may also be a p− substrate. In the case when a p− substrate is used, there is no need for the first p− epitaxial layer 31.

The pixel array is covered by a protective layer 24 that acts as a passivation and planarization layer for the imager 20. Protective layer 24 may be a layer of BPSG, PSG, BSG, silicon dioxide, silicon nitride, polyimide, or other well-known light transmissive insulator.

A color filter layer 100 is formed over the passivation layer 24. The color filter layer 100 comprises an array of red, blue and green sensitive elements which may be arranged in a pattern understood by the person having ordinary skill in the art as exemplified by U.S. Pat. Nos. 6,783,900 and 3,971,065, which are herein incorporated by reference.

As also depicted in the figures, a micro-lens 70 is formed above each pixel cell. Each micro-lens 70 is formed such that its focal point is centered over the photosensitive elements in the corresponding pixel cell. A spacer layer 25 is also formed under the mircolens 70 and under the color filter layer 100. The thickness of spacer layer 25 is adjusted such that the photosensitive element is at a focal point for the light traveling through lenses 70.

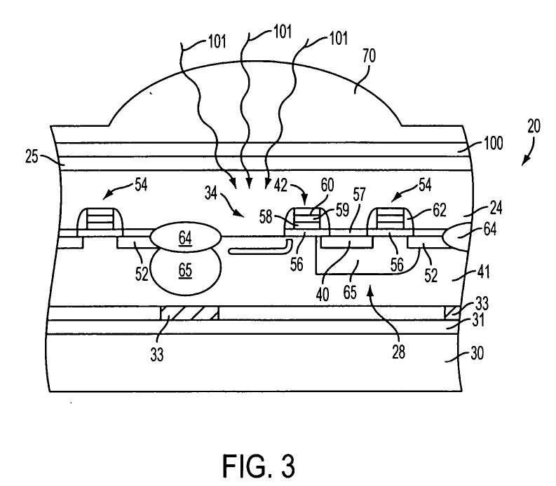

As shown in FIG. 1, p− epitaxial layer 31 is formed over a p+ substrate 30 of the pixel cell array. An n+ region 33 is formed in the p− epitaxial layer 31. In FIG. 1, the n+ region 33 is shown as being formed under the entire pixel cell array. When the n+ region 33 is formed under the isolation regions 64 (FIG. 3) there is a better ground in the array and less reduction in red quantum efficiency. FIG. 3 shows the n+ region formed under the isolation regions 64. As will be understood, when the n+ region 33 is formed under the isolation regions 64 throughout the pixel sensor array, the n+ regions 33 will form a grid throughout the pixel array. Forming the n+ region 33 under the entire pixel cell array (FIG. 1) provides the advantages of lower cross-talk and allows for easier processing. In both FIGS. 1 and 3, the n+ region 33 is patterned and does not extend significantly outside of the pixel array.

The n+ region 33 may be biased positive in operation. The n+ region 33 is preferably biased in operation at a positive voltage between 0.5V and Vdd. When the n+ region 33 is biased positive, dark current electrons formed in the substrate below the n+ region 33 are collected in the n+ region 33 and swept away prior to reaching the photosensor 34. Electrons generated from photons between photosensors 34 or those generated deep in the substrate and most prone to aggravate cross-talk are also collected in n+ region 33 and swept away, thereby reducing cross-talk. Electrons from pixel blooming will also be collected in n+ region 33.

A patterned n+ region 33, either continuous in the array as illustrated in FIG. 1 or between pixels as illustrated in FIG. 3, provides the benefits as discussed above (i.e., reduced cross-talk, blooming and dark current) without adding unwanted substrate resistance or parasitic coupling in the periphery circuits/logic.

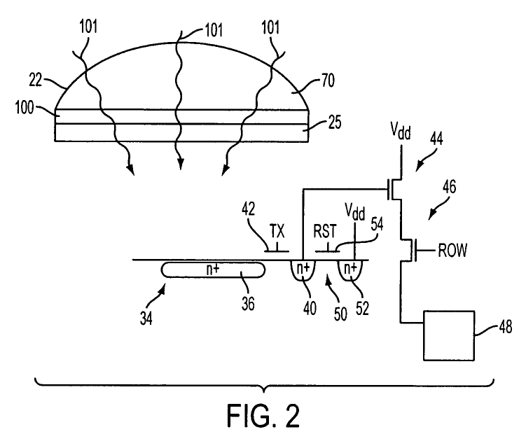

As shown in FIGS. 1-3, each pixel sensor cell contains a photosensor 34, which may be a photodiode, photogate, or the like. A pinned photodiode photosensor 34 is depicted in FIGS. 1-3. When incident radiation 101 in the form of photons passes color filter layer 100 and strikes the photosensor 34, the photo-generated electrons accumulate in the doped region 36. A transfer transistor 42 is located next to the photosensor 34, and has source and drain regions 36, 40 and a gate stack controlled by a transfer control signal TX. The drain region 40 is also called a floating diffusion region, and it stores charge received from the photosensor 34. The charges are applied to the gate of a source follower transistor 44 and converted to an output signal to row select transistor 46 which is then output to readout circuitry 48 and to an array column line. A reset transistor 50 comprised of doped regions 40, 52 and gate stack 54 is controlled by a reset control signal RST which operates to reset the floating diffusion region 40 to a predetermined initial voltage just prior to signal readout. Details of the formation and function of the above-described elements of a pixel sensor cell 28 may be found, for example, in U.S. Pat. Nos. 6,376,868 and 6,333,205, the disclosures of which are incorporated by reference herein.

As illustrated in FIGS. 1 and 3, the gate stacks 42, 54 for the transfer 42 and reset 54 transistors include a silicon dioxide or silicon nitride gate dielectric 56 over the p− epitaxial layer 41. A conductive layer 58 of doped polysilicon, tungsten, or other suitable material is formed over the insulating layer 56, and is covered by an insulating cap layer 60 of, for example, silicon dioxide, silicon nitride, or ONO (oxide-nitride-oxide). A silicide layer 59 may be used between the polysilicon layer 58 and the cap 60, if desired. Insulating sidewalls 62 are also formed on the sides of the gate stacks 42, 54. These sidewalls 62 may be formed of, for example, silicon dioxide, silicon nitride, or ONO. A field oxide isolation layer 64 around the pixel sensor cell 28 serves to isolate it from other pixel cells in the array. P-well or p-type implant regions 65 provide additional isolation between pixel cells in the array. Transfer transistor 42 is optional, in which case the diffusion regions 36 and 40 are connected together.

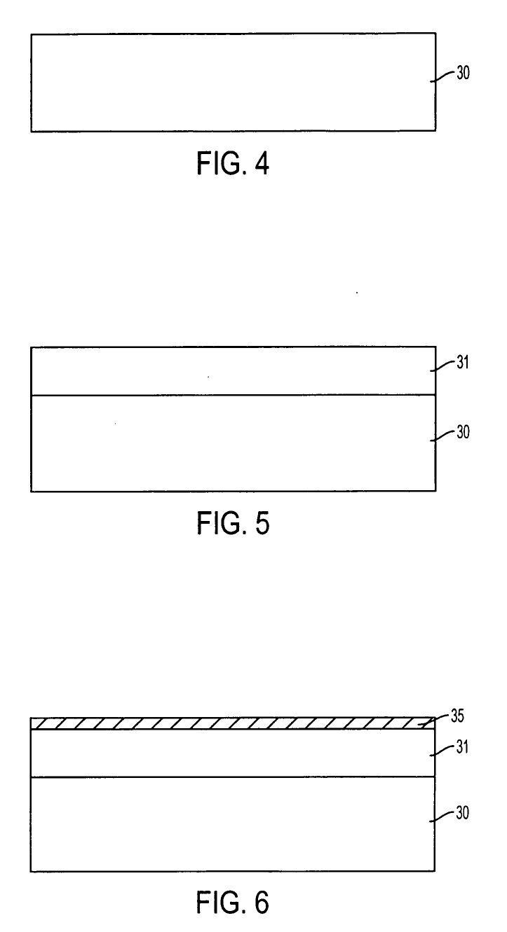

The imager device 20 described above with reference to FIGS. 1-3 is manufactured through a process described as follows, and illustrated in FIGS. 4-9. Referring now to FIG. 4, a substrate 30, which may be any of the types of substrates described above is shown. The substrate 30 is preferably a p+ substrate. It should be understood that the substrate 30 could also be formed of a p− material. If the substrate 30 is formed of a p− material, then in the process according to the present invention the p− epitaxial layer 31 discussed below can be omitted.

Reference is now made to FIG. 5 which shows the device according to FIG. 4 at a further stage of processing. Where the substrate 30 is a p+ material, a p− epitaxial layer 31 is grown over substrate 30. The p− epitaxial layer 31 is made conductive by adding an impurity element, such as, for example, boron which has one less valence electron than the semiconductive material, to form a p− type material. The p− epitaxial layer 31 can be formed from standard materials, such as, for example, silicon tetrachloride or silane. Preferably the p− exitaxial layer 31 is formed from silane.

The p− epitaxial layer 31 is grown to form a transition between the p+ substrate 30 and the p− epitaxial layer 31. The p− epitaxial layer 31 may be grown with any method for growing single-crystal silicon. The thickness of the p-epitaxial layer 31 is from about 0.05 μm to about 5.0 μm, preferably from about 0.5 μm to about 1.5 μm.

Reference is now made to FIG. 6 which shows the device according to FIG. 5 at a further stage of processing. An oxide layer 35 is deposited over the p-epitaxial layer 31. The oxide layer 35 is formed over the p− epitaxial layer 31 by conventional methods such as, for example, chemical vapor deposition or thermal oxidation. A preferred method to form oxide layer 35 is thermal oxidation by exposing the surface of the p− epitaxial layer 31 in an oxygen atmosphere at an elevated temperature. The oxide layer 35 preferably has a thickness of about 20 angstroms to about 500 angstroms.

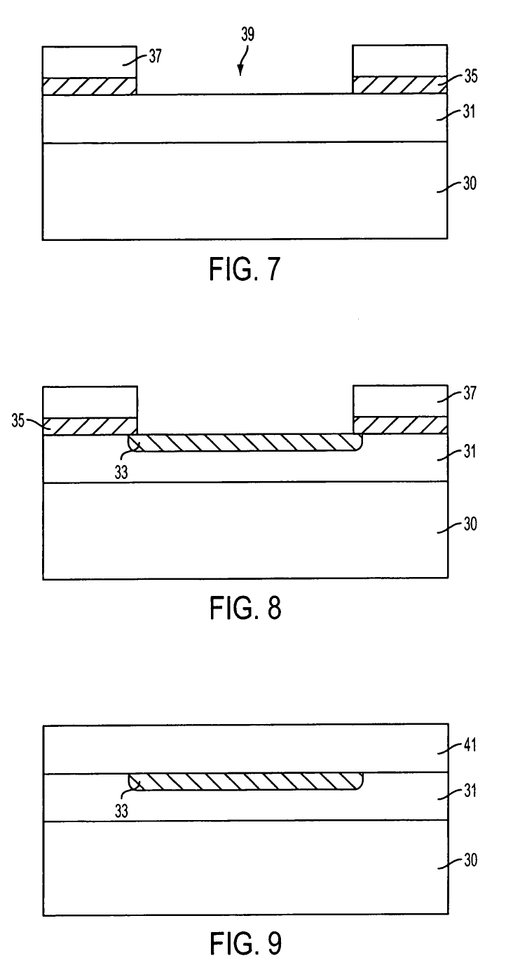

Reference is now made to FIG. 7 which shows the substrate according to FIG. 6 at a further stage of processing. The oxide layer 35 is patterned with photoresist layer 37 and etched to form opening 39. The portion of the oxide layer 35 which is removed to form opening 39 is removed by conventional photoresist patterning and etching of the oxide layer 35. It should be noted that the oxide layer 35 under the photoresist layer 37 is the preferred approach to prevent photoresist contamination of the wafer. The oxide layer 35 may be formed from any suitable material, such as nitride or ONO. In addition, with proper cleaning techniques, the photoresist layer 37 could be applied directly to the p− epitaxial layer 31, without the oxide layer 35.

Reference is now made to FIG. 8 which shows the substrate according to FIG. 7 at a further stage of processing. N+ doped region 33 is formed in p− epitaxial layer 31. The n+ doped region 33 is formed by implanting a dopant into p− epitaxial layer 31. N+ doped region 33 is doped with a dopant implant by conventional methods, preferably by ion implantation. The dopants are implanted into n+ doped region 33 at a dopant concentration of from about 1×10¹⁰ ions/cm² to about 1×10¹⁸ ions/cm², preferably at a dopant concentration of from about 1×10¹³ ions/cm² to about 1×10¹⁵ ions/cm². N+ doped region 33 may be doped with any suitable dopant containing materials, for example, materials containing one or more of phosphorous or arsenic. In a preferred embodiment, the dopant is arsenic. The n+ doped region 33 is preferably doped with the dopant by ion implantation at a power of from about 15 KeV to about 50 MeV. It should be understood that the dopant concentration and power will vary depending upon a variety of physical parameters such as, for example, the material being implanted, the processing stage of the semiconductor substrate, the amount of material to be removed and other factors. Depending on the alignment tolerances, it may be necessary to pattern and etch a notch or mark in the backside of the substrate 30 at the time of the n+ implant so as to align the n+ region 33 with the pixel array of the imager for later processing and alignment.

According to the present invention, it is possible to connect the n+ doped region 33 with an n-well region in an imager device. The n-well, while not disclosed in the figures, is known in the imager devices discussed above and incorporated by reference. The incorporation of an n-well in imaging devices described herein are known to the person having ordinary skill in the art. For example, it may be necessary to connect the n+ doped region 33 with the n-well to make adequate top-side contact between the imager device and the n+ doped region.

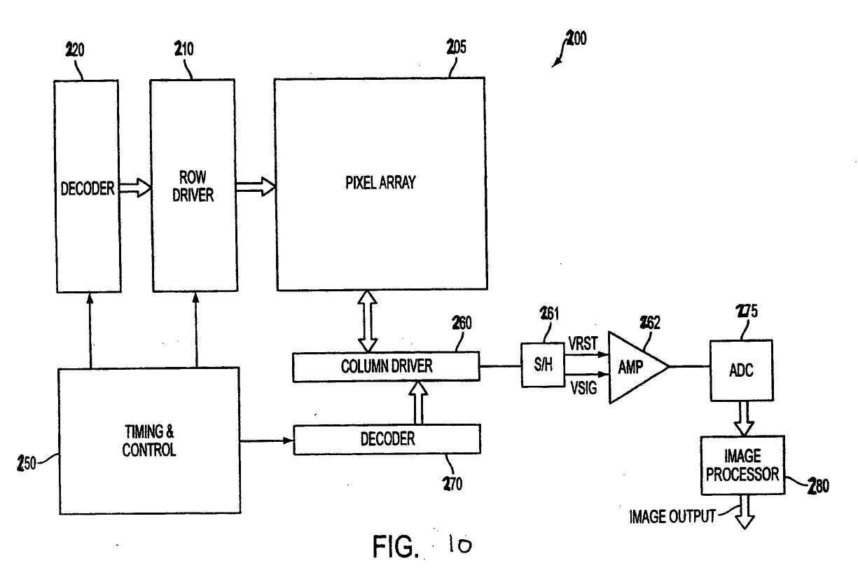

Reference is now made to FIG. 9 which shows the substrate according to FIG. 8 at a further stage of processing. The photoresist 37 and oxide layer 35 are stripped off by conventional methods. A second p− epitaxial layer 41 is grown over p-epitaxial layer 31. The p− epitaxial layer 41 may be grown with any method for growing single-crystal silicon. The thickness of the p− epitaxial layer 41 is from about 0.5 μm to about 20.0 μm, preferably from about 2.5 μm to about 4.0 μm. The p− epitaxial layer 41 is doped with a concentration of from about 1×10¹⁰ ions/cm² to about 1×10²⁰ ions/cm², preferably at a dopant concentration of from about 1×10¹⁴ ions/cm² to about 1×10¹⁵ ions/cm². P− epitaxial layer 41 may be doped with any suitable dopant containing materials, for example, materials containing boron.

From the resultant structure illustrated in FIG. 9, an image device is formed by standard imager processing. An exemplary imager is illustrated in FIGS. 1-3. Exemplary CMOS imaging circuits, processing steps thereof, and detailed descriptions of the functions of various CMOS elements of an imaging circuit are described, for example, in U.S. Pat. No. 6,140,630, U.S. Pat. No. 6,376,868, U.S. Pat. No. 6,310,366, U.S. Pat. No. 6,326,652, U.S. Pat. No. 6,204,524, and U.S. Pat. No. 6,333,205, each of which is assigned to Micron Technology, Inc.

While the processes have been described with reference to a CMOS imager device, it should be understood that the process may be also used with pixel cells of other types of imagers as well, for example, with a CCD imager. Accordingly, the pixel cell formed as described above may be employed in CCD image sensors as well as CMOS image sensors.

The n+ doped layer 33 reduces cross-talk, blooming and dark current by collecting excess electrons in the imaging device. As discussed below, the n+ doped layer 33 may be biased positive to aid in electron collection within the imaging device. The biasing of the region can be accomplished by well known techniques for biasing a region.

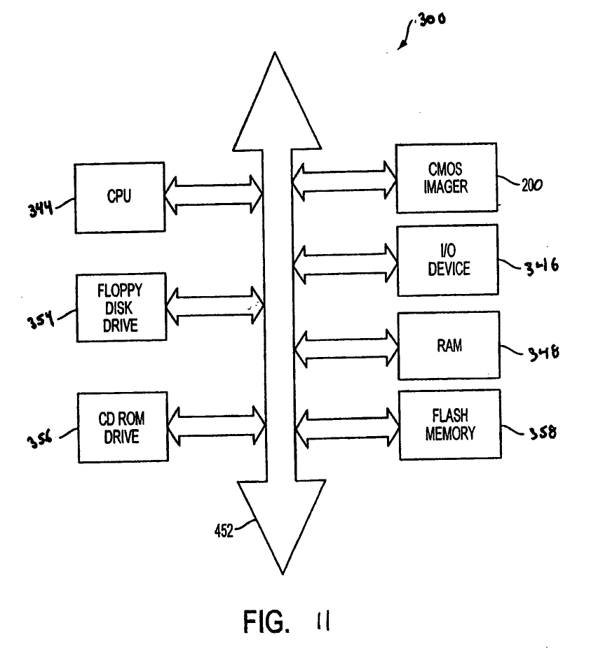

FIG. 10 illustrates an exemplary imager 200 that may utilize any embodiment of the invention. The imager 200 has a pixel array 205 comprising pixel cells constructed as described above with respect to FIGS. 1-9. Row lines are selectively activated by a row driver 210 in response to row address decoder 220. A column driver 260 and column address decoder 270 are also included in the imager 200. The imager 200 is operated by the timing and control circuit 250, which controls the address decoders 220, 270. The control circuit 250 also controls the row and column driver circuitry 210, 260.

A sample and hold (S/H) circuit 261 associated with the column driver 260 reads a pixel reset signal Vrst and a pixel image signal Vsig for selected pixel cells. A differential signal (Vrst−Vsig) is amplified by differential amplifier (AMP) 262 for each pixel and is digitized by analog-to-digital converter 275 (ADC). The analog-to-digital converter 275 supplies the digitized pixel signals to an image processor 280, which forms a digital image.

If desired, the imager 200 may be combined with a processor, such as a CPU, digital signal processor or microprocessor. The imager 200 and the microprocessor may be formed in a single integrated circuit. An exemplary processor system 300 using a CMOS imager having a n+ region in accordance with the present invention is illustrated in FIG. 11. A processor based system is exemplary of a system having digital circuits which could include CMOS or other imager devices. Without being limiting, such a system could include a computer system, camera system, scanner, machine vision system, vehicle navigation system, video telephone, surveillance system, auto focus system, star tracker system, motion detection system, image stabilization system and other image processing systems.

As shown in FIG. 11, an exemplary processor system 300, for example, a camera generally comprises a central processing unit (CPU) 344, e.g., a microprocessor, that communicates with an input/output (I/O) device 346 over a bus 352. The imager 200 also communicates with the system over bus 352. The computer system 300 also includes random access memory (RAM) 348, and may include peripheral devices such as a floppy disk drive 454, a compact disk (CD) ROM drive 356 or a removable memory or a flash memory 358 which also communicate with CPU 344 over the bus 352. The floppy disk 454, the CD ROM 356 or flash memory 358 stores images captured by imager 200. The imager 200 is preferably constructed as an integrated circuit as previously described with respect to FIGS. 1-9.

While the invention has been described in detail in connection with exemplary embodiments known at the time, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Accordingly, the invention is not to be seen as limited by the foregoing description, but is only limited by the scope of the appended claims.

What is claimed as new and desired to be protected by Letters Patent of the United States is:

1. An imager comprising:
a substrate having a first conductivity type with a first dopant concentration level;
an epitaxial layer having a first conductivity type with a second dopant concentration level formed on said substrate;
a doped region having a second conductivity type formed in at least a part of said epitaxial layer; and
an array of pixel sensor cells comprising a plurality of pixel cells formed at a first surface of said epitaxial layer.

2. The imager according to claim 1, wherein said substrate is doped to a P+ conductivity type.

3. The imager according to claim 1, wherein said epitaxial layer is doped to a P− conductivity type.

4. The imager according to claim 3, wherein said doped region is doped to an N+ conductivity type.

5. The imager according to claim 1, wherein said doped region is formed under said array in the entirety of said epitaxial layer.

6. The imager according to claim 1, wherein said imager further includes isolation regions separating said plurality of pixel cells in said array of pixel cells and said doped region is formed as a grid under said isolation regions.

7. The imager according to claim 4, wherein said doped region has a dopant concentration of from about 1×10¹⁰ ions/cm² to about 1×10¹⁸ ions/cm².

8. The imager according to claim 4, wherein said doped region has a dopant concentration of from about 1×10¹³ ions/cm² to about 1×10¹⁵ ions/cm².

9. The imager according to claim 1, wherein said imager is a CMOS imager.

10. The imager according to claim 1, wherein said imager is a CCD imager.

11. An imager comprising:
a substrate having a first conductivity type with a first dopant concentration level;
a first epitaxial layer having a first conductivity type with a second dopant concentration level formed on said substrate;
a doped region having a second conductivity type formed in at least a part of said first epitaxial layer;
a second epitaxial layer having a first conductivity type with a second dopant concentration level formed over said first epitaxial layer; and
an array of pixel sensor cells comprising a plurality of pixel cells formed at a first surface of said second epitaxial layer.

12. The imager according to claim 11, wherein said substrate is doped to a P+ conductivity type.

13. The imager according to claim 11, wherein said first and second epitaxial layers are both doped to a P− conductivity type.

14. The imager according to claim 11, wherein said doped region is doped to an N+ conductivity type.

15. The imager according to claim 11, wherein said doped region is formed in the entirety of said first epitaxial layer.

16. The imager according to claim 14, wherein said doped region has a dopant concentration of from about 1×10¹⁰ ions/cm² to about 1×10¹⁸ ions/cm².

17. The imager according to claim 14, wherein said doped region has a dopant concentration of from about 1×10¹³ ions/cm² to about 1×10¹⁵ ions/cm².

18. The imager according to claim 11, wherein said doped region is formed under said array in the entirety of said epitaxial layer.

19. The imager according to claim 11, wherein said imager further includes isolation regions separating said plurality of pixel cells in said array of pixel cells and said doped region is formed as a grid under said isolation regions.

20. The imager according to claim 11, wherein said imager is a CMOS imager.

21. The imager according to claim 11, wherein said imager is a CCD imager.

22. An imager comprising:
a substrate having a first conductivity type with a first dopant concentration level;
a doped region having a second conductivity type formed in at least a part of said substrate layer;
an epitaxial layer having a first conductivity type with a second dopant concentration level formed over said substrate; and
an array of pixel sensor cells comprising a plurality of pixel cells formed at a first surface of said epitaxial layer.

23. The imager according to claim 22, wherein said substrate and said epitaxial layer are both doped to a P− conductivity type.

24. The imager according to claim 22, wherein said doped region is doped to an N+ conductivity type.

25. The imager according to claim 22, wherein said doped region is formed in the entirety of said substrate.

26. The imager according to claim 22, wherein said imager further includes isolation regions separating said plurality of pixel cells in said array of pixel cells and said doped region is formed as a grid under said isolation regions.

27. The imager according to claim 24, wherein said doped region has a dopant concentration of from about 1×10¹³ ions/cm² to about 1×10¹⁵ ions/cm².

28. The imager according to claim 22, wherein said imager is a CMOS imager.

29. The imager according to claim 22, wherein said imager is a CCD imager.

30. A processor system comprising:
a substrate having a first conductivity type with a first dopant concentration level;
an epitaxial layer having a first conductivity type with a second dopant concentration level formed on said substrate;
a doped region having a second conductivity type formed in at least a part of said epitaxial layer;
an array of pixel sensor cells comprising a plurality of pixel cells formed at a first surface of said epitaxial layer; and
a processor for receiving and processing data representing the image.

31. The processor system according to claim 30, wherein said arrays and said processor are formed on a single substrate.

32. The processor system according to claim 30, wherein said substrate is doped to a P+ conductivity type.

33. The processor system according to claim 30, wherein said epitaxial layer is doped to a P− conductivity type.

34. The processor system according to claim 33, wherein said doped region is doped to an N+ conductivity type.

35. The processor system according to claim 30, wherein said doped region is formed in the entirety of said epitaxial layer.

36. The processor system according to claim 34, wherein said doped region has a dopant concentration of from about 1×10¹³ ions/cm² to about 1×10¹⁵ ions/cm².

37. The processor system according to claim 30, wherein said imager further includes isolation regions separating said plurality of pixel cells in said array of pixel cells and said doped region is formed as a grid under said isolation regions.

38. A processor system comprising:
a substrate having a first conductivity type with a first dopant concentration level;
a first epitaxial layer having a first conductivity type with a second dopant concentration level formed on said substrate;
a doped region having a second conductivity type formed in at least a part of said first epitaxial layer;
a second epitaxial layer having a first conductivity with a second dopant concentration level type formed over said first epitaxial layer;
an array of pixel sensor cells comprising a plurality of pixel cells formed at a first surface of said second epitaxial layer; and
a processor for receiving and processing data representing the image.

39. The processor system according to claim 38, wherein said arrays and said processor are formed on a single substrate.

40. The processor system according to claim 38, wherein said substrate is doped to a P+ conductivity type.

41. The processor system according to claim 38, wherein said first and second epitaxial layers are both doped to a P− conductivity type.

42. The processor system according to claim 38, wherein said doped region is doped to an N+ conductivity type.

43. The processor system according to claim 38, wherein said doped region is formed in the entirety of said first epitaxial layer.

44. The processor system according to claim 38, wherein said imager further includes isolation regions separating said plurality of pixel cells in said array of pixel cells and said doped region is formed as a grid under said isolation regions.

45. The processor system according to claim 42, wherein said doped region has a dopant concentration of from about 1×10¹³ ions/cm² to about 1×10¹⁵ ions/cm².

46. A method of forming an imaging device, said method comprising:
providing a substrate having a first conductivity type with a first dopant concentration level;
forming a first epitaxial layer having a first conductivity type with a second dopant concentration level over said substrate;
forming a doped region having a second conductivity type in said first epitaxial layer;
forming a second epitaxial layer having a first conductivity type with a second dopant concentration level over said first epitaxial layer; and
forming an array of pixel sensor cells formed at an upper surface of said second epitaxial layer.

47. The method according to claim 46, wherein said doped region is N+ doped formed by ion implantation.

48. The method according to claim 47, wherein said doped region is doped with arsenic.

49. The method according to claim 46, wherein said substrate has a P+ conductivity type.

50. The method according to claim 46, wherein said first and second epitaxial layer both have a P− conductivity type.

51. The method according to claim 50, wherein said second epitaxial layer has a thickness of from about 0.5 μm to about 20.0 μm.

52. The method according to claim 46, wherein said second epitaxial layer is doped with boron.

53. A method of forming an imaging device, said method comprising:
providing a substrate having a first conductivity type with a first dopant concentration level;
forming a doped region having a second conductivity type in said substrate;
forming an epitaxial layer having a first conductivity type with a second dopant concentration level over said substrate; and
forming an array of pixel sensor cells formed at an upper surface of said epitaxial layer.

54. The method according to claim 53, wherein said doped region is N+ doped formed by ion implantation.

55. The method according to claim 54, wherein said doped region is doped with arsenic.

56. The method according to claim 53, wherein said substrate and said epitaxial layer both have a P− conductivity type.

57. The method according to claim 53, wherein said epitaxial layer has a thickness of from about 0.5 μm to about 20.0 μm.

58. The method according to claim 57, wherein said epitaxial layer is doped with boron.
